(19) United States
(12) Patent Application Publication
(10) Pub. No.: US 2023/0217596 A1
(43) Pub. Date: Jul. 6, 2023

(54) FLEXIBLE CIRCUIT BOARD

(71) Applicant: FLEXIUM INTERCONNECT, INC., Kaohsiung City (TW)

(72) Inventors: Wei-Kuo CHEN, Kaohsiung city (TW); Chung-Yi CHEN, Kaohsiung city (TW); Hui-Wen HUANG, Kaohsiung city (TW)

(21) Appl. No.: 18/067,022

(22) Filed: Dec. 16, 2022

(30) Foreign Application Priority Data
Dec. 30, 2021 (TW) 110149520

(51) Int. Cl. H05K 1/18; H05K 1/02; H05K 3/46; H05K 1/11

(52) U.S. Cl. CPC H05K 1/189; H05K 1/028; H05K 3/4652; H05K 1/115; H05K 1/118; H05K 2201/0141; H05K 2201/10098; H05K 2201/096; H05K 2201/0215

(57) ABSTRACT

A flexible circuit board includes liquid crystal polymer (LCP) layers and metal layers including circuit routes. Each of the LCP layers includes via structures. The metal layers and the LCP layers are alternatively stacked to form a multi-layer structure. Adjacent metal layers are electrically connected through the via structures. Some via structures of different LCP layers are substantially aligned with one another to form a stack of via structures. Each of the via structures includes openings filled with conductive material. The size of the opening fulfils the following equation: Vb≥cos(Bh/Vh)*Vt/k*2, where Vb is a diameter of a smaller aperture, Vt is a diameter of a bigger aperture, Vh is a combined thickness of a LCP layer and a metal layer, Bh is a thickness of a LCP layer and k is a tensile modulus.

### RELATED APPLICATIONS

This application claims priority to Taiwan Application Serial Number 110149520, filed Dec. 30, 2021, which is herein incorporated by reference.

### BACKGROUND

### Field of Invention

The present invention relates to a flexible circuit board, in particular to multi-layer flexible circuit board with Liquid Crystal Polymer layers.

### Description of Related Art

Electronic products such as personal computer (PC), tablet PC, notebook (NB) and smart phone are becoming part of our daily lives. In order to provide various functions to meet users' demands, electric components used in electronic products are fabricated in various configurations. For example, electric components are foldable to reduce the volume of electronic products to meet users' demands for the convenience to carry the electronic products.

Flexible circuit boards are known for their foldable characteristics. A conventional flexible circuit board includes insulation layers and circuit layers. Through holes, blind holes or buried holes in the insulation layers and the circuit layers are formed with electroplating process to achieve electrical connection between the circuit layers.

### SUMMARY

The present invention provides a flexible circuit board, a three-dimensional structure of a circuit module and fabrication method thereof. A via structure stack is provided to replace conventional electroplated through holes, blind holes and/or buried holes in multiple layers. Accordingly, the number of the electroplating processes used for fabrication can be decreased, the size of the via structure can be reduced, the number of stacked layers of the flexible circuit board can be increased. Hence the product design may be smaller, and the flexibility of the flexible circuit board is improved.

In accordance with an embodiment of the present invention, the flexible circuit board includes a plurality of liquid crystal polymer (LCP) layers and a plurality of metal layers. Each of the LCP layers includes via structures. The metal layers and the LCP layers are alternatively stacked to form a multi-layer structure. Each of the via structures is configured to electrically connect adjacent two of the metal layers to each other. Each of the LCP layers has at least one of the via structures substantially aligned with another one of the via structures in another one of the LCP layers to form a via-structure stack. Each of the via structures has an opening and conductive material filled in the opening to enable the via structures to be electrically connected to the circuit routes of adjacent two of the metal layers, thereby forming a stack structure for continuous electric connection. The opening has a side wall having a tilt angle so that the shape of the cross-section of each of the via structures is trapezoid shaped, and the relationship between a smaller aperture and a larger aperture of the opening fulfills the following equation:

Vb≥cos(Bh/Vh)*Vt/k*2

where Vb is a diameter of the smaller aperture, Vt is a diameter of the larger aperture, Vh is a combined thickness of one of the LCP layers and adjacent one of the metal layers, and Bh is a thickness of the one of the LCP layer and k is a tensile modulus.

In some embodiments, the via structures are substantially aligned where the offset between adjacent two of the via structures is equal to or smaller than 75 um.

In some embodiments, the LCP layers are directly connected with the metal layers in the multi-layer structure, and a tensile thereof is equal to or greater than 3 Gpa.

In some embodiments, the multi-layer structure includes at least three LCP layers and at least three metal layers alternatively stacked, each one of the LCP layers includes at least one aligned via structure, and a thickness variation between adjacent two of the LCP layers is under 10%.

In some embodiments, material of the metal layers includes copper, silver, gold, aluminum, nickel, iron or an alloy thereof.

In some embodiments, the conductive material is an electroplated layer

In some embodiments, a number of the LCP layers in the via-structure stack where the via structures are disposed is equal to or greater than 3.

In some embodiments, the multi-layer structure has a structure surface comprising at least one electric component, and the at least one electric component is electrically connected to at least one of the metal layers.

In some embodiments, the multi-layer structure includes at least one bending portion.

In some embodiments, at least one of the metal layers includes a circuit of antenna.

In accordance with an embodiment of the present invention, the flexible circuit board includes a plurality of LCP layers, a plurality of metal layers and at least one electric component. Each of the LCP layers includes via structures. The metal layers and the LCP layers are alternatively stacked to form a multi-layer structure, and each of the via structures is configured to electrically connect adjacent two of the metal layers to each other. Electric components may be disposed on a surface of the multi-layer structure. Each of the LCP layers has at least one of the via structures substantially aligned with another one of the via structures in another one of the LCP layers to form a via-structure stack. Each one of the via structures has an opening filled with conductive material to enable the via structures to electrically connect the circuit routes of adjacent two of the metal layers, thereby forming a stack structure for continuous electrical connections. The multi-layer structure has at least one bending portion defining an inner side and an outer side, and the at least one electric component is located at the inner side.

In some embodiments, the multi-layer structure is fabricated by laminating at least six single-sided circuit boards and at least one metal foil.

In some embodiments, the multi-layer structure is fabricated by laminating at least seven single-sided circuit boards.

### BRIEF DESCRIPTION OF THE DRAWINGS

The invention can be more fully understood by reading the following detailed description of the embodiment, with reference made to the accompanying drawings as follows.

FIG. 1 is a schematic diagram showing a cross section view of a structure of a flexible circuit board in accordance with an embodiment of the present invention.

FIG. 2 is a schematic diagram showing the structure of the via-structure stack in accordance with an embodiment of the present invention.

FIG. 3 is a schematic diagram showing a structure of the circuit route in a metal layer in accordance with an embodiment of the present invention.

FIG. 4 is a schematic diagram showing a flow chart of a fabrication method for the 3D circuit structure module in accordance with embodiments of the present invention.

FIGS. 5A-5E are schematic diagrams showing structures corresponding to the fabrication method for the 3D circuit structure module in accordance with embodiments of the present invention.

FIG. 6 is a schematic diagram showing a structure of an antenna module in accordance with embodiments of the present invention.

FIG. 7 is a schematic diagram showing a structure of a bending antenna module in accordance with embodiments of the present invention.

FIG. 8 is a schematic diagram showing a flow chart of a fabrication method for the 3D circuit structure module in accordance with embodiments of the present invention.

FIGS. 9A-9F are schematic diagrams showing structures corresponding to the fabrication method for the 3D circuit structure module in accordance with embodiments of the present invention.

FIG. 10 is a schematic diagram showing a flow chart of a fabrication method for the 3D circuit structure module in accordance with embodiments of the present invention.

FIGS. 11A-11F are schematic diagrams showing structures corresponding to the fabrication method for the 3D circuit structure module in accordance with embodiments of the present invention.

### DETAILED DESCRIPTION

Specific embodiments of the present invention are further described in detail below with reference to the accompanying drawings, however, the embodiments described are not intended to limit the present invention and it is not intended for the description of operation to limit the order of implementation. Moreover, any device with equivalent functions that is produced from a structure formed by a recombination of elements shall fall within the scope of the present invention. Additionally, the drawings are only illustrative and are not drawn to actual sizes and proportions.

The using of “first”, “second”, “third”, etc. in the specification should be understood for identifying units or data described by the same terminology but are not referred to particular order or sequence.

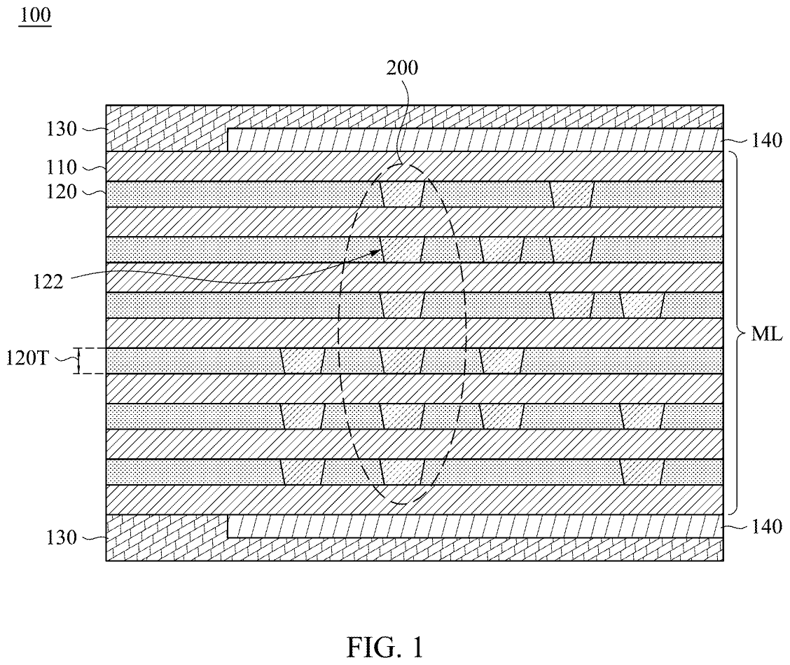

FIG. 1 is a schematic diagram showing a cross section view of the structure a flexible circuit board 100 in accordance with an embodiment of the present invention. The flexible circuit board 100 includes plural metal layers 110 and plural insulation layers 120. The metal layers 110 and the insulation layers 120 are alternatively stacked to form a multi-layer structure ML. Each of the metal layers 110 may include circuit routes to provide inner electric connections in each of the metal layers 110. The insulation layers 120 have via structures 122 to provide electric connections between the metal layers 110. In some embodiments, a via structure 122 in an insulation layer 120 is aligned with another via structure 122 in another insulation layer 120 to form a via-structure stack.

In some embodiments, material of the metal layers 110 comprises copper, silver, gold, aluminum, nickel, iron or an alloy thereof, and material of the insulation layers 120 is liquid crystal polymer (LCP). However, embodiments of the present invention are not limited thereto. Other suitable metal material and insulation material may also be used to form the metal layers 110 and the insulation layers 120 as required customizations. For example, Polyimide (PI) or modified PI (MPI) is common insulation material. In some embodiments, cover lays (CVLs) 130 can be disposed on the top surface and the bottom surface of the multi-layer structure ML, and glue layers 140 are disposed between the cover lays 130 and the multi-layer structure ML.

In some embodiments of the present invention, the multi-layer structure ML includes at least three metal layers 110 and at least three insulation layers 120, and the variation between thicknesses 120T of adjacent two of the insulation layers 120 is ranged from 0% to 10%. Further, the insulation layers 120 are directly in contact with the metal layers 110 in the multi-layer structure ML, and a tensile thereof is equal to or greater than 3 Gpa.

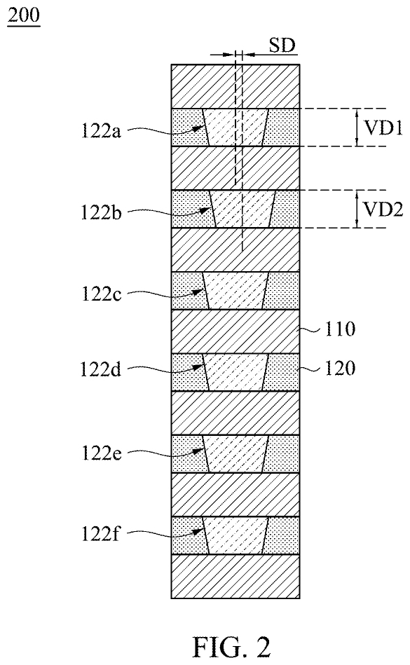

Referring FIG. 2, FIG. 2 is a schematic diagram showing the via-structure stack 200 in accordance with an embodiment of the present invention. The via-structure stack 200 includes via structures 122 located in the insulation layers. In some embodiments, the number of the via structures 122 continuously stacked in the via-structure stack 200 is greater than three. In this embodiment, the via-structure stack 200 includes six continuously stacked via structures comprising a first via structure 122a, a second via structure 122b, a third via structure 122c, a fourth via structure 122d, a fifth via structure 122e and a sixth via structure 122f. The via structures 122a-122f are located in adjacent insulation layers 120 to electrically connect the circuit routes in adjacent metal layers 110 to form a stack structure for continuous electric connection. The via structures 122a-122f in the via-structure stack 200 are aligned with each other. In this embodiment, the offset between two adjacent via structures 122a-122f is equal to or smaller than 75 um. For example, the offset SD between center lines of the adjacent first via structure 122a and the second via structure 122b is equal to or smaller than 75 um. Furthermore, the variation between heights of the via structures 122a-122f is equal to or smaller than 10%. For example, the first via structure 122a has a height VD1, the second via structure 122b has a height VD2, wherein the variation between the height VD1 and the height VD2 is equal to or smaller than to 10%.

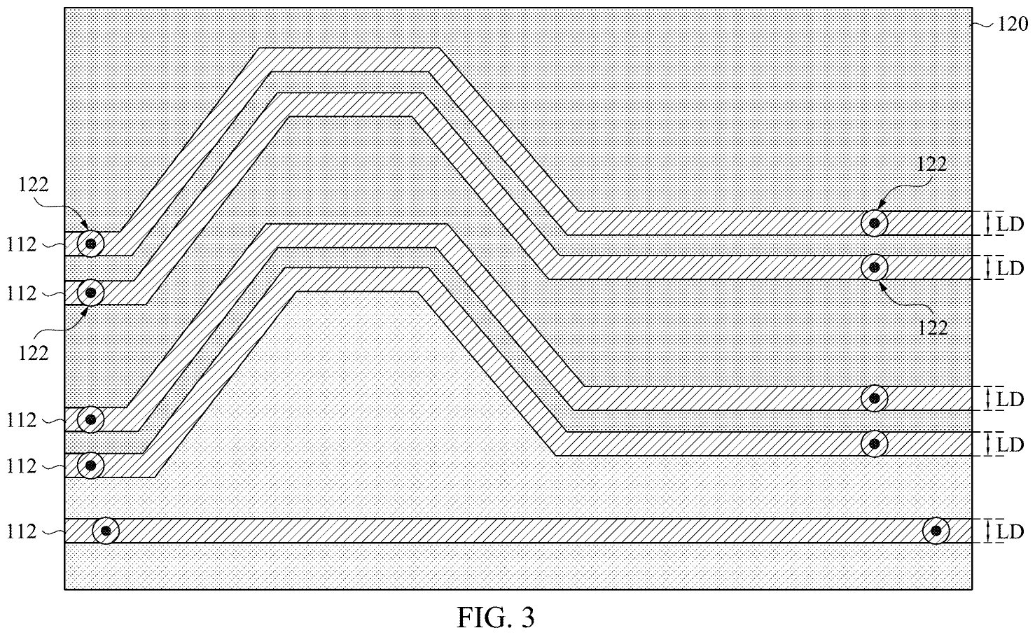

Referring to FIG. 3, FIG. 3 is a schematic diagram showing a structure of the circuit route in a metal layer 110 in accordance with an embodiment of the present invention. The metal layer 110 may be customized to include various circuit structures. For example, as shown in FIG. 3, the metal layer 110 may include circuit routes 112 located on an insulation layer 120. The circuit routes 112 may be electrically connected to circuit routes in another metal layer 110 through the via structure of the insulation layer 120. The circuit routes 112 in the metal layer 110 of the embodiments have a smaller line width and a higher route density. For example, the line width LD of the circuit route 112 in the metal layer 110 is equal to or less than 50 um. In another embodiment, the distance between adjacent two of the circuit routes 112 may be designed to be equal to or smaller than 50 um. In addition, the thickness difference between any two of the routes 112 is in a range of ±5 um. In other words, the uniformity among the circuit routes 112 in the metal layers 110 is ±5 um.

It may be understood from the above descriptions that the flexible circuit board 100 of the present invention provides a 3D circuit structure module including the multi-layer structure ML. The multi-layer structure ML includes the via-structure stack 200 to provide electric connections between different metal layers, where the via-structure stack 200 includes via structures 122a-122f aligned with each other. The 3D circuit structure of the present invention may be designed to have smaller trace and via size. Therefore, the number of the traces in the 3D circuit structure module may be increased, and a smaller flexible circuit board 100 is made possible.

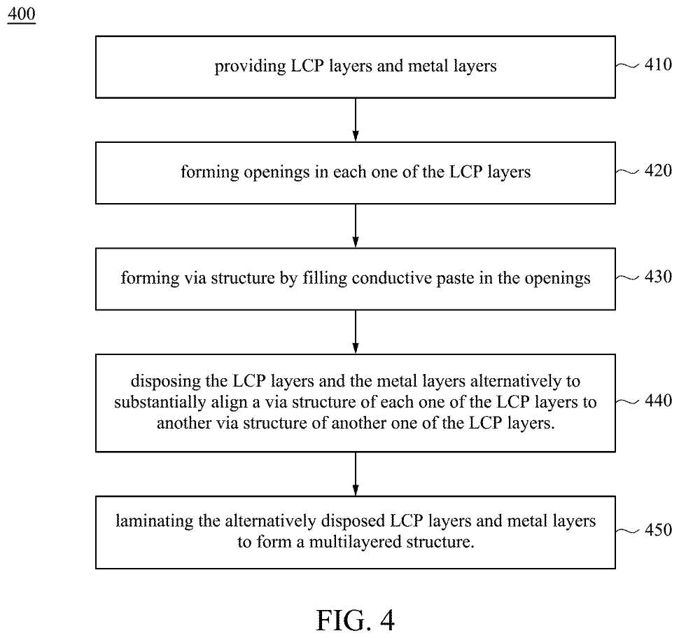

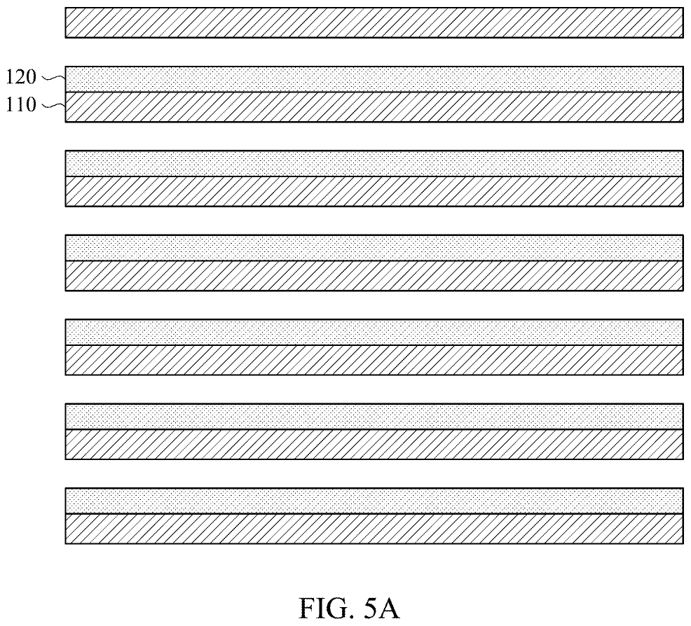

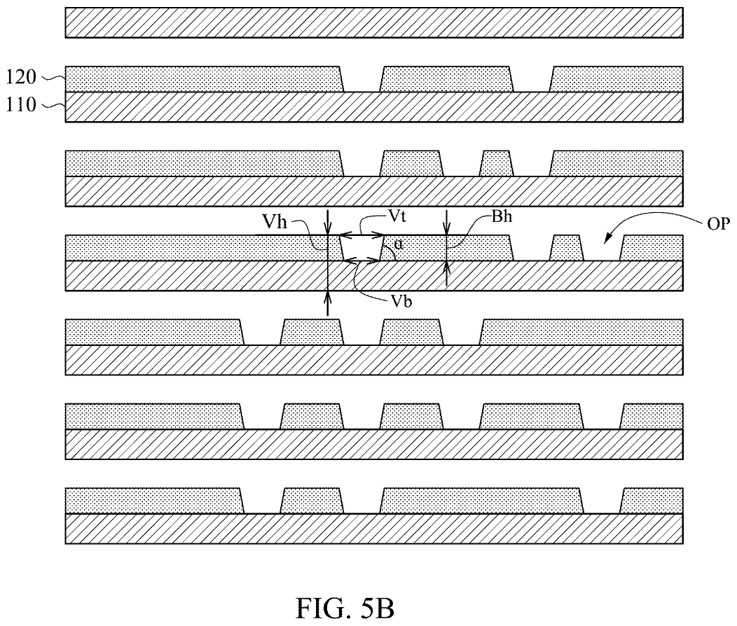

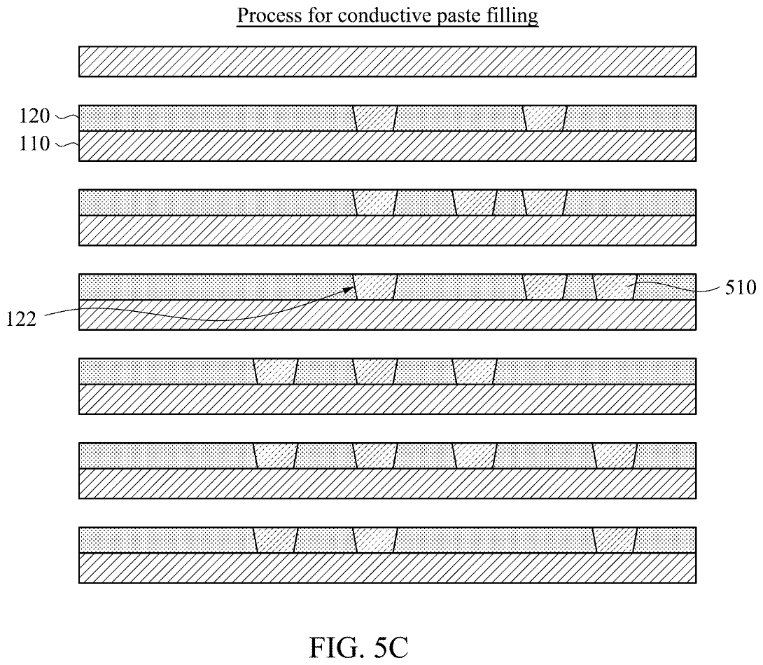

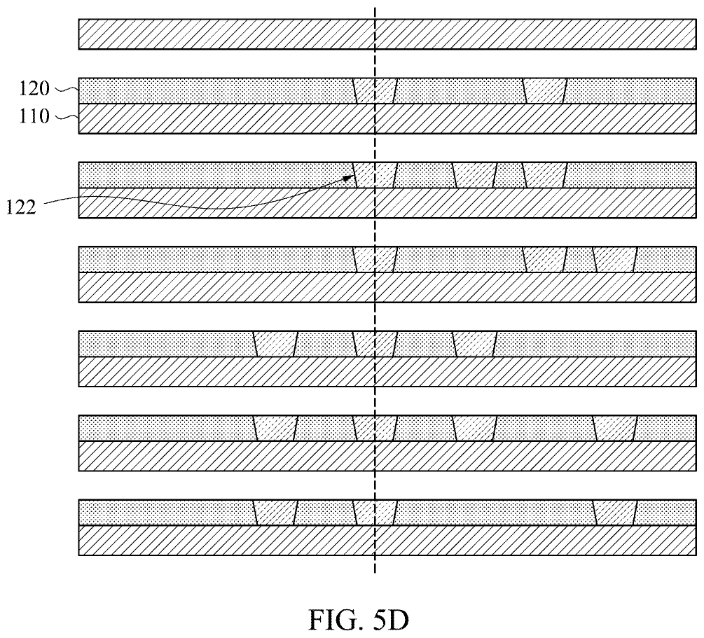

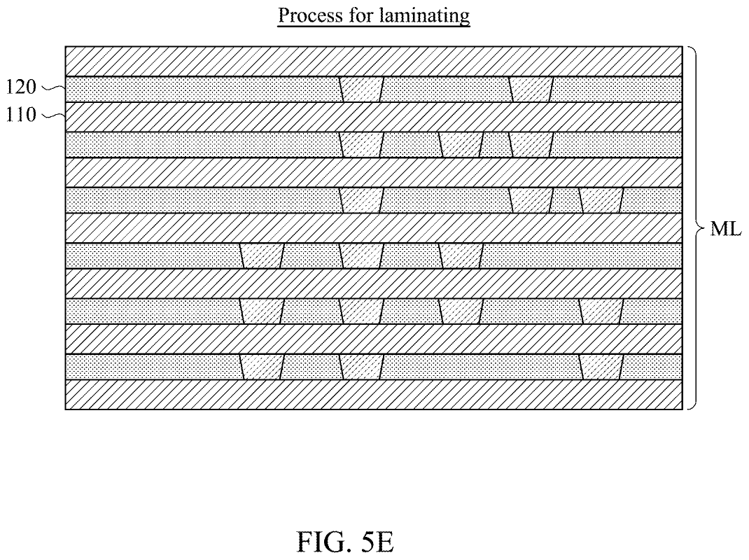

Referring to FIG. 4, FIG. 4 is a schematic diagram showing a flow chart of a fabrication method 400 for the 3D circuit structure module in accordance with embodiments of the present invention. In this fabrication method 400, first step 410 is performed to prepare the metal layers 110 and the insulation layers 120 (hereinafter referred as “liquid crystal polymer layer(s)” or LCP), as shown in FIG. 5A. In this embodiment, step 410 provides six LCP layers 120 and seven metal layers 110, but other embodiments are not limited thereto. More or less LCP layers 120 and metal layers 110 may be provided depending on design specifications. In some embodiments, step 410 provides at least four LCP layers 120 and at least five metal layers 110.

Step 420 is performed for forming via (for example, using an etching process) on each LCP layers 120 to form openings OP, as shown in FIG. 5B. In this embodiment, the side wall of each opening OP has a tilt angle α, such that the cross-section of the opening OP is in a shape of trapezoid. The opening OP has a larger diameter Vt and a smaller diameter Vb fulfilling following equation:

Vb≥cos(Bh/Vh)*Vt/k*2 (1)

where Vh is the total height of the metal layer 110 and the LCP layer 120, Bh is the height of the LCP layer 120, and k is a tensile modulus.

Then, step 430 is performed to fill conductive material (conductive paste) into the openings OP to form the via structures 122 as shown in FIG. 5C. In this embodiment, the conductive paste 510 is made from copper, tin, bismuth or an alloy thereof. However, other embodiments of the present invention are not limited thereto. In some embodiments, the conductive paste 510 can be made from gold, silver, copper, carbon, carbon nanotube and compounds thereof. Thereafter, step 440 is performed to dispose the metal layers 110 and the liquid crystal polymer layers 120 alternatively, and to substantially align the via structures 122 in different LCP layers 120, as shown in FIG. 5D. Referring to FIG. 2, the offset between any adjacent two via structures 122 is smaller than 75 um. In some embodiments, the via structures 122 may be formed by using an electroplating process to fill the conductive material into the openings OP.

Thereafter, step 450 is performed to press the alternatively disposed metal layers 110 and the liquid crystal polymer layers 120 to form the multi-layer structure ML, as shown in FIG. 5E. In some embodiments of the present invention, the metal layers 110 and the LCP layers 120 are pressed directly. In other words, the multi-layer structure ML does not contain any glue layers for binding the metal layers 110 with the liquid crystal polymer layers 120.

In the fabrication method 400 for the 3D circuit structure module in accordance with some embodiments of the present invention, six single-sided circuit boards and one metal foil are pressed to form the multi-layer structure ML, but other embodiments of the present invention are not limited thereto. In other embodiments of the present invention, seven single-sided circuit boards are pressed to form the multi-layer structure ML, or five single-sided circuit boards and one double-sided circuit board are pressed to form the multi-layer structure ML.

In some embodiments, the above equation (1) is applied to designs of the openings OP, so that the conductive paste 510 are substantially filled in the openings OP without overflowing when the metal layers 110 and the liquid crystal polymer layers 120 are subsequently pressed. Circuit abnormalities caused by overflowing conductive paste 510 may be avoided.

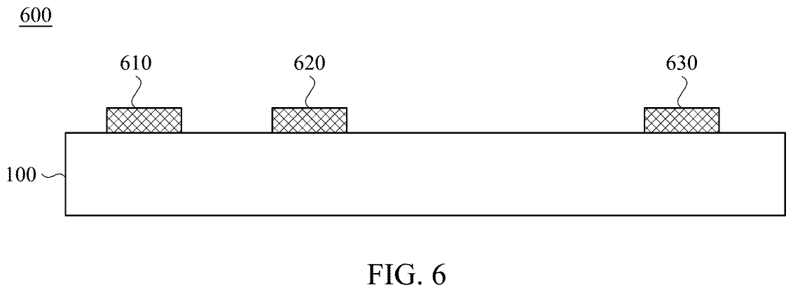

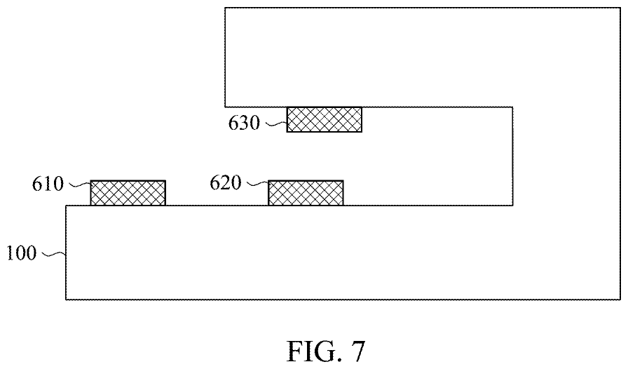

Referring to FIG. 6, FIG. 6 is a schematic diagram showing a structure of an antenna module 600 in accordance with embodiments of the present invention. The antenna module 600 includes the above flexible circuit board 100, a RF (Radio Frequency) IC 610, and antenna devices 620, 630. In this embodiment, the antenna module 600 may be formed by using AiP (Antenna in Packaging) technology. Comparing to conventional packaging technology, the AiP in this embodiment further integrates antenna devices and achieves a smaller module size. In this embodiment, the RF IC 610 and the antenna devices 620, 630 are disposed on the same surface of the flexible circuit board 100. After the antenna module 600 is bent, the space occupied by the antenna module 600 can be reduced by using the above design, as shown in FIG. 7. After the antenna module 600 is bent, the RF IC 610 and the antenna devices 620, 630 are located in the inner side of the antenna module 600, and thus the space occupied by the bent antenna module 600 may be significantly receded. In some embodiments, circuits of the flexible circuit board 100 may be used to form antenna devices, and thus the antenna devices 620, 630 can be omitted, and the space occupied by the antenna module 600 may be further reduced.

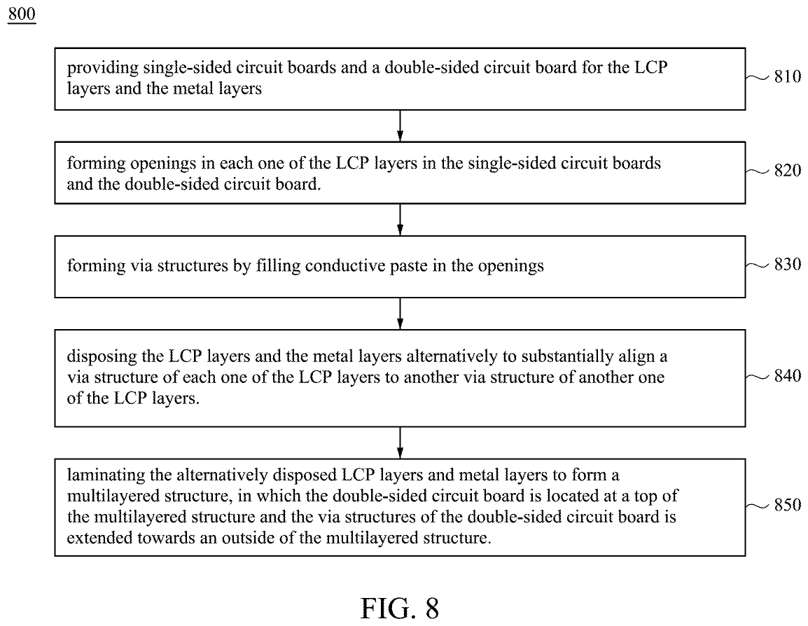

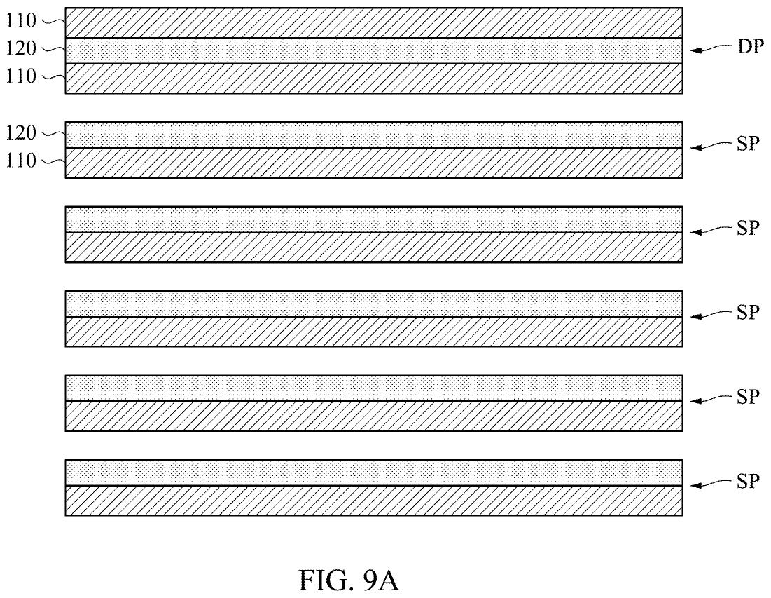

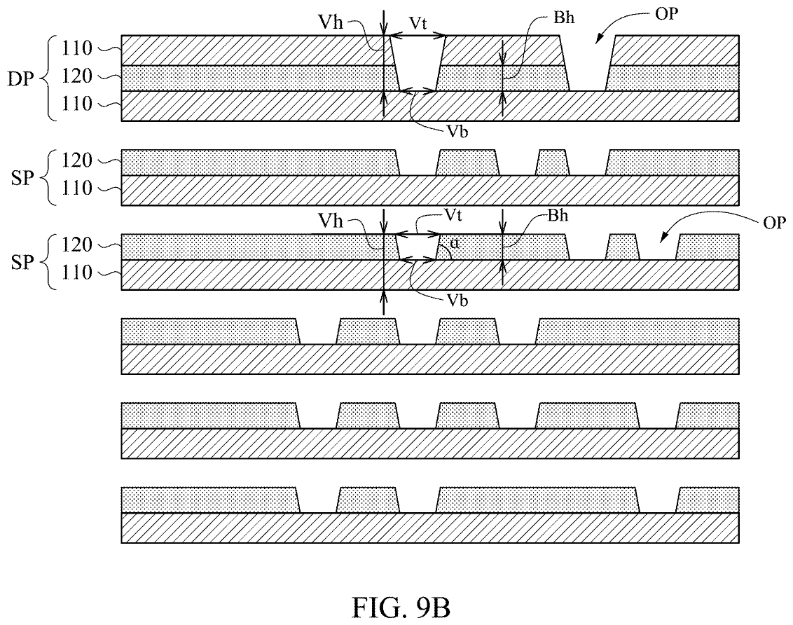

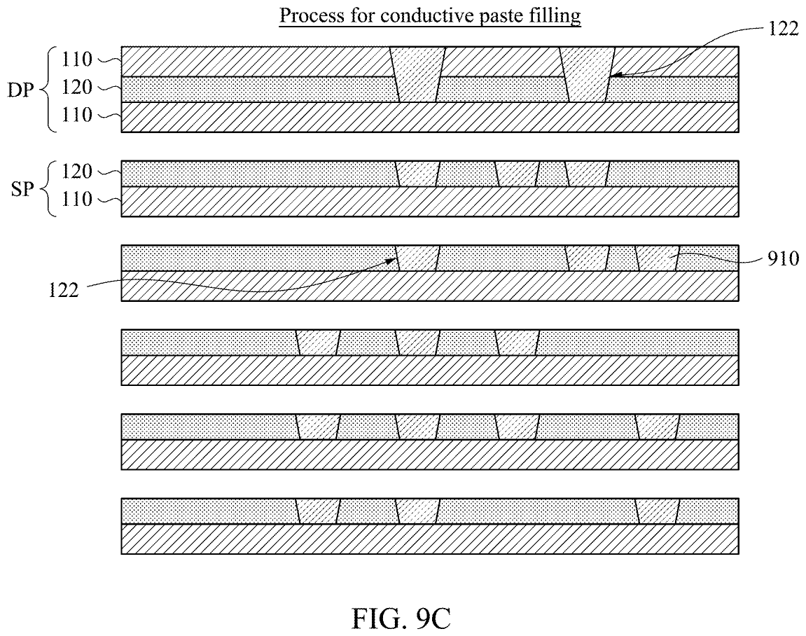

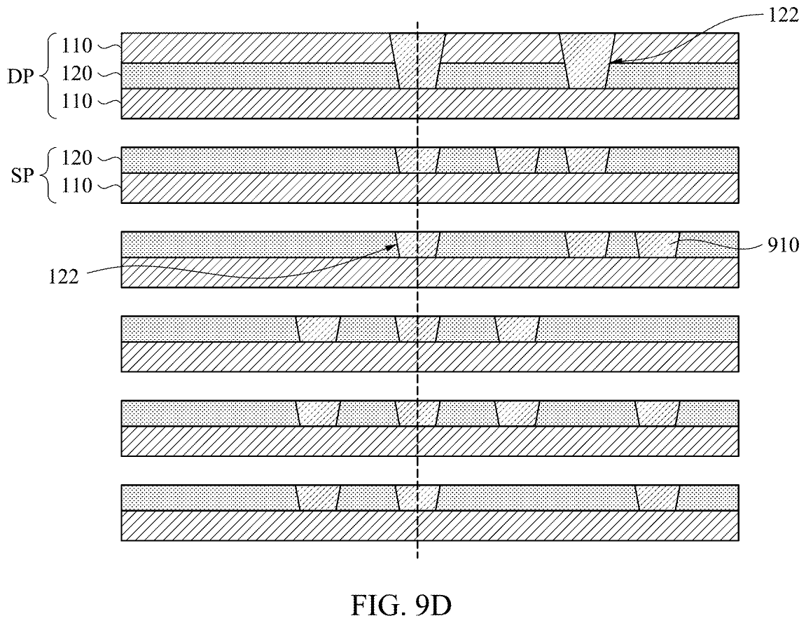

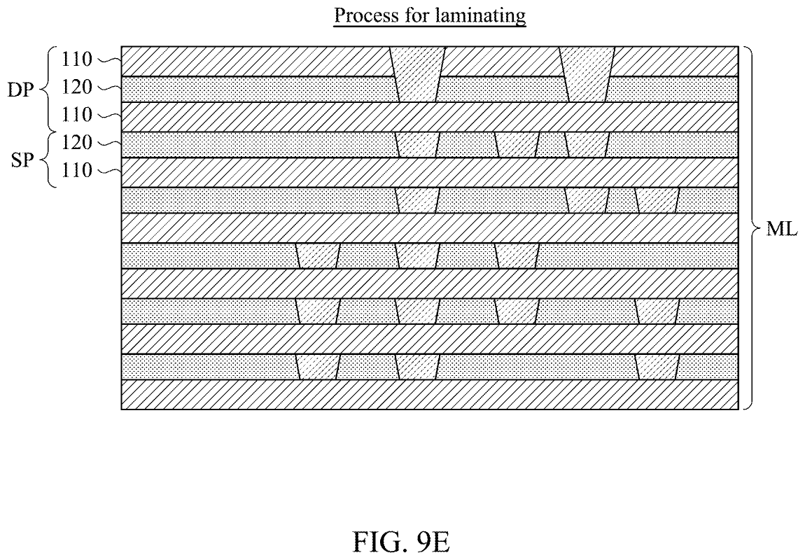

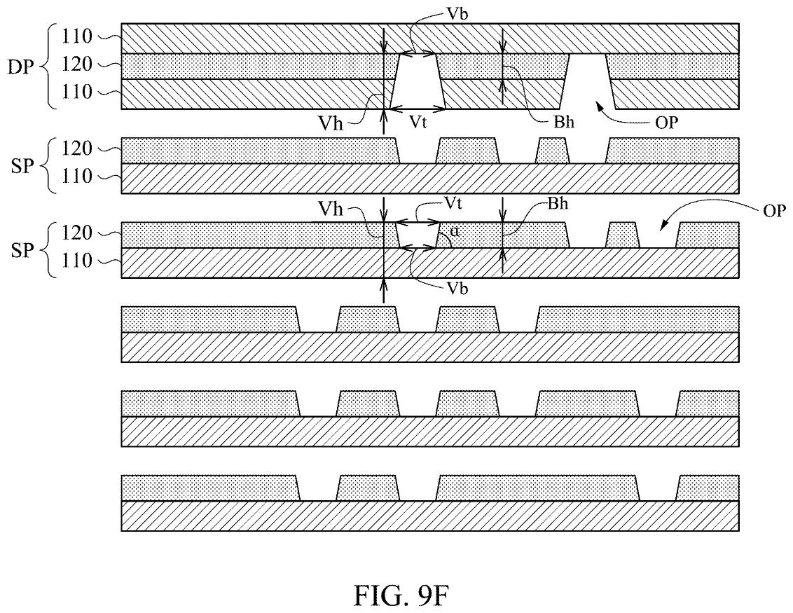

Referring to FIG. 8, FIG. 8 is a schematic diagram showing a flowchart of a fabrication method 800 for the 3D circuit structure module in accordance with embodiments of the present invention. In the fabrication method 800 for the 3D circuit structure module, first step 810 is performed to prepare the metal layers 110 and the LCP layers 120, as shown in FIG. 9A. In this embodiment, step 810 prepares five single-sided circuit boards SP and one double-sided circuit board DP to form six LCP layers 120 and seven metal layers 110.

Then, step 820 is to perform a via forming process (for example, an etching process) on each of the LCP layers 120 to form plural openings OP respectively, as shown in FIG. 9B. In this embodiment, the side wall of each of the openings OP has a tilt angle α, such that the cross-section of the opening OP is in a shape of trapezoid. The opening OP has a larger diameter Vt and a smaller diameter Vb fulfilling the above equation (1). In addition, when the etching process is performed on the LCP layers 120 of the double-sided circuit board DP, the metal layer 110 of the top side of the double-sided circuit board DP is etched. The larger diameter Vt and the smaller diameter Vb of the openings OP in the double-sided circuit board DP also fulfill the equation (1).

Then, step 830 is to fill conductive paste 910 into the openings OP to form the via structures 122 as shown in FIG. 9C. In this embodiment, the conductive paste 910 is similar to the conductive paste 510, and descriptions of the materials may be referred thereto. Following step 830, step 840 is to dispose the metal layers 110 and the LCP layers 120 alternatively, and to substantially align one of the via structures 122 in each of the LCP layers 120 with another one of the via structures 122 in another LCP layer 120, as shown in FIG. 9D. Referring to FIG. 2 again, the offset between centers of any two of the via structures 122 is smaller than 75 um. In this embodiment, step 830 has the double-sided circuit board DP disposed on the single-sided circuit boards SP and the via structures 122 are arranged face-up.

Thereafter, step 850 is to press the alternatively disposed metal layers 110 and the LCP layers 120 to form the multi-layer structure ML, as shown in FIG. 9E. In some embodiments, step 850 is similar to step 450, and thus the metal layers 110 and the LCP layers 120 are directly pressed to form the multi-layer structure ML, in which the double-sided circuit board DP is located at the top of the multi-layer structure ML, and the via structures 122 of the double-sided circuit board DP are arranged toward outside of the multi-layer structure ML.

Referring to FIG. 9F, a schematic diagram showing a structure corresponding to the above step 820 in accordance with embodiments of the present invention. FIG. 9F is similar to FIG. 9B, but the openings OP formed in the double-sided circuit board DP facing the openings OP formed in the single-sided circuit board SP. Then, steps 830-850 are performed to fill conductive paste 910 into the openings OP to form the via structures 122, to align the via structures 122, and to directly press the double-sided circuit board DP and the single-sided circuit boards SP.

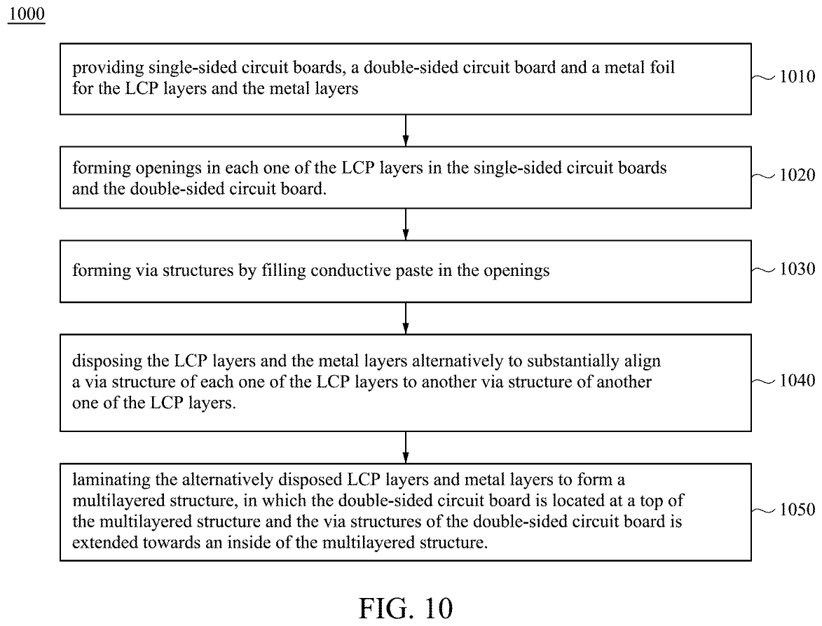

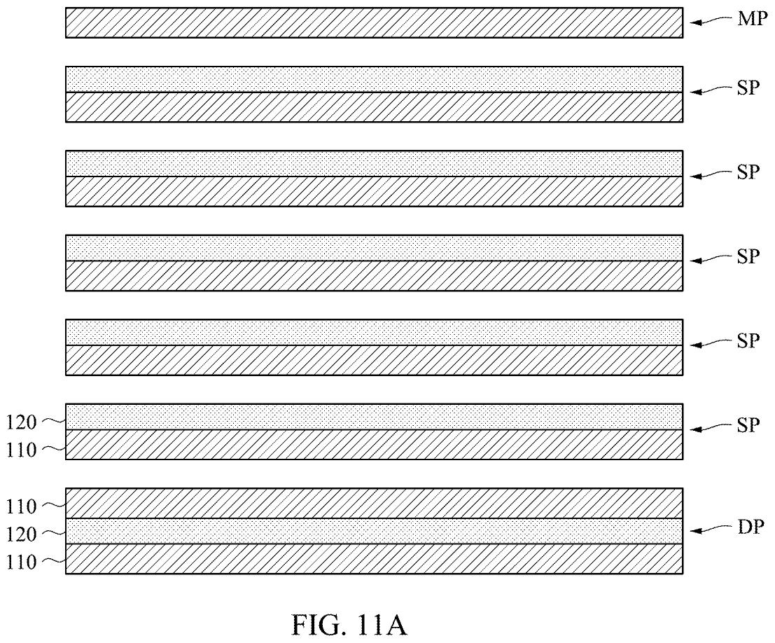

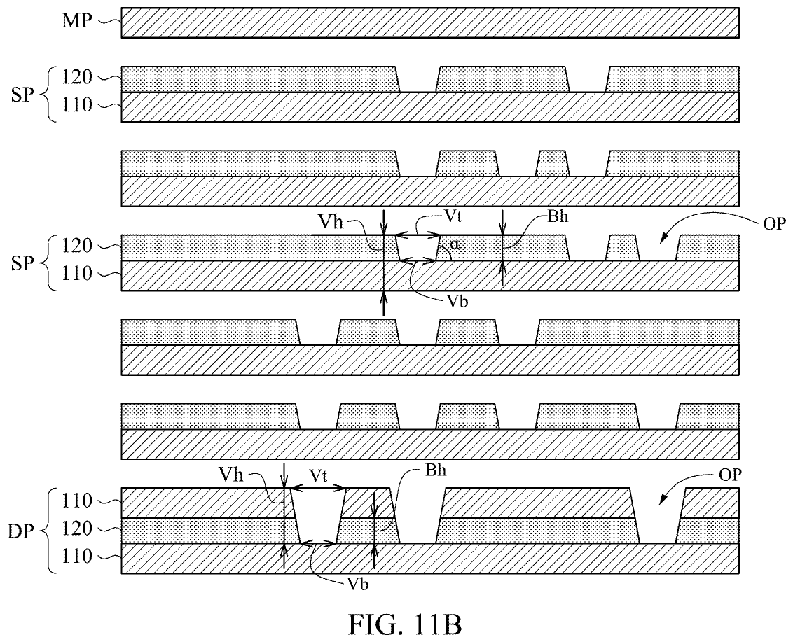

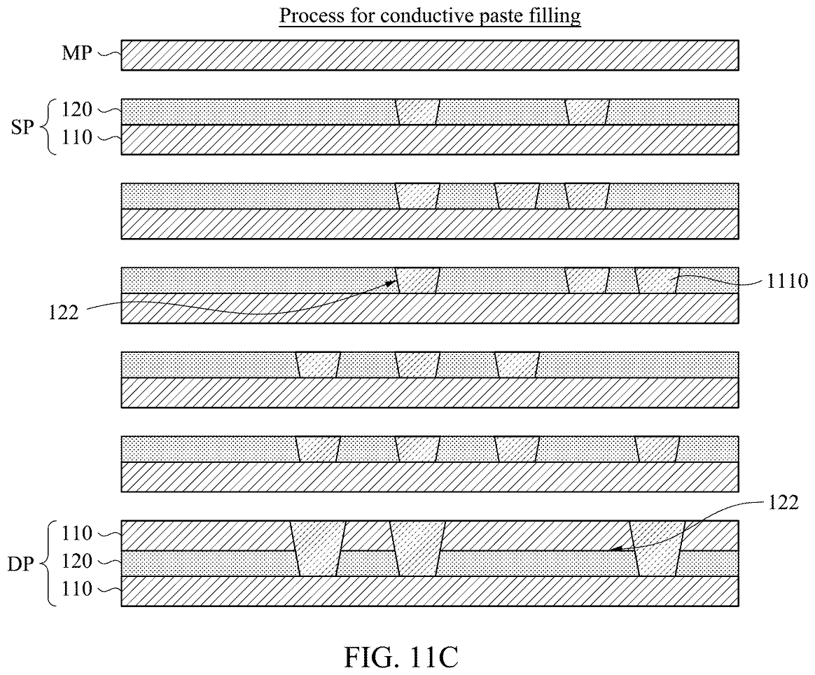

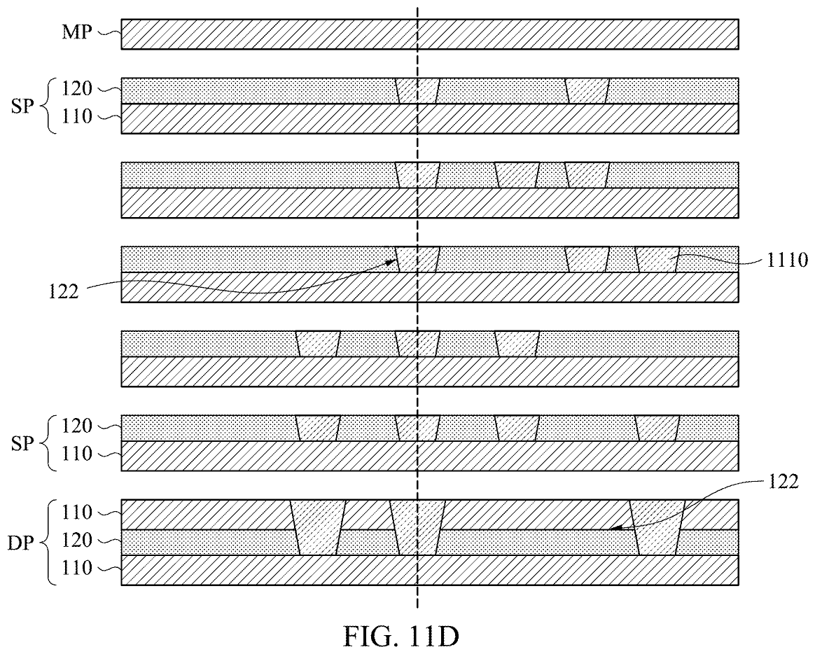

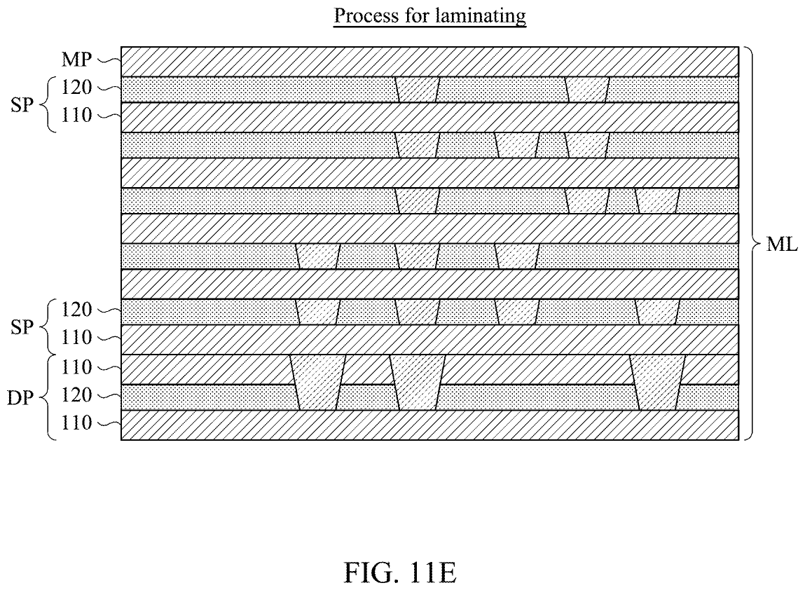

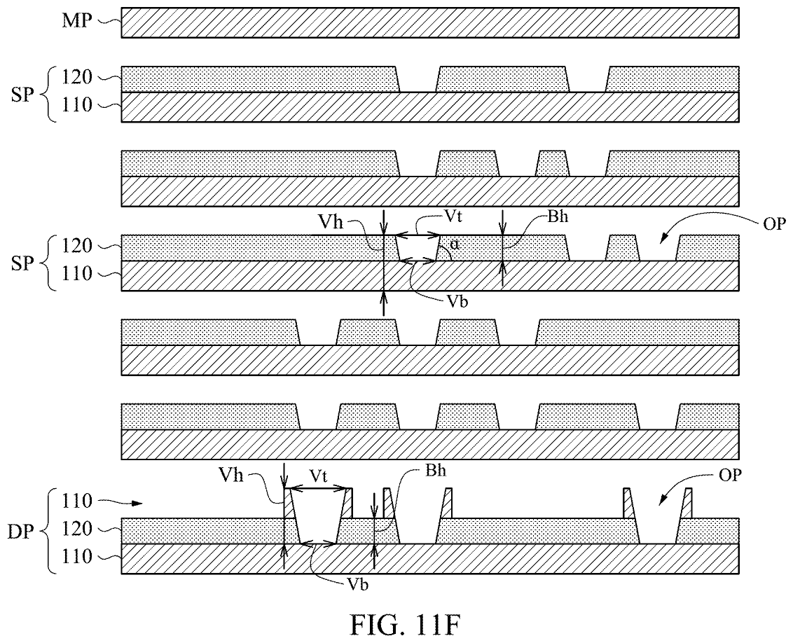

Referring to FIG. 10, FIG. 10 is a schematic diagram showing a flowchart of a fabrication method 1000 for the 3D circuit structure module in accordance with embodiments of the present invention. Firstly, step 810 is to prepare the metal layers 110 and the LCP layers 120, as shown in FIG. 11A. In this embodiment, step 1010 provides five single-sided circuit boards SP, one double-sided circuit board DP and one metal foil MP to provide six liquid crystal polymer layers 120 and eight metal layers 110.

Then, step 1020 is to perform a via-forming process (for example, an etching process) on each of the LCP layers 120 to form plural openings OP respectively, as shown in FIG. 11B. In this embodiment, a side wall of each of the openings OP has a tilt angle α, such that the cross-section of the opening OP is trapezoid shaped. The opening OP has a larger diameter Vt and a smaller diameter Vb fulfilling the equation (1). In addition, when the etching process is performed on the LCP layers 120 of the double-sided circuit board DP, the metal layer 110 of the top side of the double-sided circuit board DP is etched. The larger diameter Vt and the smaller diameter Vb of the double-sided circuit board DP also fulfilling the above equation (1).

Then, step 1030 is to fill conductive paste 1110 into the openings OP to form via structures 122 as shown in FIG. 11C. In this embodiment, the material of the conductive paste 1110 is similar to the material of the conductive paste 510, and descriptions of the materials may be referred thereto. Following step 1030, step 1040 is performed to dispose the metal layers 110 and the LCP layers 120 alternatively, and to substantially align one of the via structures 122 in each one of the liquid crystal polymer layers 120 with another via structure 122 in another liquid crystal polymer layer 120, as shown in FIG. 11D. Referring to FIG. 2 again, the offset between centers of any two of the via structures 122 is smaller than 75 um. In this embodiment, step 1030 has the double-sided circuit board DP disposed under the single-sided circuit boards SP and the via structures 122 arranged toward the single-sided circuit boards SP.

Thereafter, step 1050 is to press the alternatively disposed metal layers 110 and the liquid crystal polymer layers 120 to form the multi-layer structure ML, as shown in FIG. 11E. In some embodiments, step 1050 is similar to step 450, and thus the metal layers 110 and the liquid crystal polymer layers 120 are directly pressed to form the multi-layer structure ML, in which the double-sided circuit board DP is located at the bottom of the multi-layer structure ML, and the via structures 122 of the double-sided circuit board DP are arranged toward inside of the multi-layer structure ML.

Referring to FIG. 11F, a schematic diagram showing a structure corresponding to the above step 1020 in accordance with embodiments of the present invention. FIG. 11F is similar to FIG. 11B, but the double-sided circuit board DP is further processed (for example etched), and the metal portions surrounding the openings remain. Then, steps 1030-1050 are performed to fill conductive paste 1110 into the openings OP to form the via structures 122, to align the via structures 122, and to directly press the double-sided circuit board DP and the single-sided circuit boards SP. In this embodiment, the metal layer 110 of the double-sided circuit board DP is etched and the metal portions surrounding the openings remain to form solid via structures 122 after pressing the double-sided circuit board DP and the single-sided circuit boards SP.

It can be understood from the above descriptions that the fabrication methods 800 and 1000 for the 3D circuit structure module in the embodiments of the present invention provide various cases that plural single-sided circuit boards and one double-sided circuit board are used to form the multi-layer structure ML to provide the flexible circuit board having the via-structure stack 200.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A flexible circuit board, comprising:
a plurality of liquid crystal polymer (LCP) layers, wherein each of the LCP layers comprises via structures; and
a plurality of metal layers having a plurality of circuit routes, wherein the metal layers and the LCP layers are alternatively stacked to form a multi-layer structure, and each of the via structures is configured to electrically connect adjacent two of the metal layers;
wherein each of the LCP layers has at least one via structure substantially aligned with another via structure in another LCP layer to form a via-structure stack;
wherein each of the via structures has an opening filled with conductive material to enable the via structures to electrically connect the circuit routes of adjacent two metal layers, thereby forming a stack structure for continuous electric connections;
wherein the opening has a side wall having a tilt angle to form a trapezoid shape in a cross-section, and a relationship between a smaller aperture and a larger aperture of the opening fulfills the following equation:
Vb≥cos(Bh/Vh)*Vt/k*2
where Vb is a diameter of the smaller aperture, Vt is a diameter of the larger aperture, Vh is a combined thickness of one of the LCP layers and adjacent one of the metal layers, and Bh is a thickness of the one of the LCP layer and k is a tensile modulus.

2. The flexible circuit board of claim 1, wherein an offset between adjacent two via structures is equal to or smaller than 75 um in the substantially aligned via structures.

3. The flexible circuit board of claim 1, wherein the LCP layers are directly connected with the metal layers in the multi-layer structure, and the tensile modulus is equal to or greater than 3 Gpa.

4. The flexible circuit board of claim 1, wherein the multi-layer structure comprises at least three LCP layers and at least three metal layers alternatively stacked, each of the LCP layers comprises at least one aligned via structure, and a thickness variation between adjacent two of the LCP layers is in a range from 0% to 10%.

5. The flexible circuit board of claim 1, wherein material of the metal layers comprises copper, silver, gold, aluminum, nickel, iron or an alloy thereof.

6. The flexible circuit board of claim 1, wherein a width of each of the circuit routes and a distance between adjacent two of the circuit routes in the metal layers are equal to or smaller than 50 um, and an uniformity of the circuit routes is +5 um.

7. The flexible circuit board of claim 1, wherein the conductive material is a conductive paste comprising gold, silver, copper, nickel, tin, bismuth, carbon, carbon nanotube, or a alloy thereof.

8. The flexible circuit board of claim 1, wherein the conductive material is an electroplated layer.

9. The flexible circuit board of claim 1, wherein a number of the LCP layers in the multi-layer structure with via is greater than 3.

10. The flexible circuit board of claim 1, wherein the multi-layer structure has a structure surface comprising at least one electric component electrically connected to at least one of the metal layers.

11. The flexible circuit board of claim 1, wherein the multi-layer structure comprises at least one bending portion.

12. The flexible circuit board of claim 1, wherein at least one of the metal layers comprises antenna circuit.

13. A flexible circuit board, comprising:
a plurality of liquid crystal polymer (LCP) layers, wherein each one of the LCP layers comprises via structures;
a plurality of metal layers having a plurality of circuit routes, wherein the metal layers and the LCP layers are alternatively stacked to form a multi-layer structure, and each one of the via structures is configured to electrically connect at least two of the metal layers; and
at least one electric component disposed on a surface of the multi-layer structure;
wherein each of the LCP layers has at least one of the via structures substantially aligned with another one of the via structures in another one of the LCP layers to form a via-structure stack;
wherein each one of the via structures has an opening filled with conductive material to enable the via structures to electrically connect the circuit routes of the metal layers, thereby forming a stacked structure for continuous electric connection;
wherein the multi-layer structure has at least one bending portion defining an inner side and an outer side, and the at least one electric component is located in the inner side.

14. The flexible circuit board of claim 13, wherein the multi-layer structure is fabricated by laminating six single-sided circuit boards and one metal foil.

15. The flexible circuit board of claim 13, wherein the multi-layer structure is fabricated by laminating at least five single-sided circuit boards and at least one double-sided circuit board.

16. The flexible circuit board of claim 13, wherein the multi-layer structure is fabricated by laminating at least five single-sided circuit boards, at least one double-sided circuit board, and at least one metal foil.
